(19) United States
(12) Patent Application Publication
(10) Pub. No.: US 2026/0161100 A1
(43) Pub. Date: Jun. 11, 2026

(54) STOCKER SYSTEM

(71) Applicant: BROOKS AUTOMATION (GERMANY) GMBH, Steißlingen (DE)

(72) Inventors: Lutz REBSTOCK, Gaienhofen (DE); Michael Alexander SCHWETZ, Winterthur (CH)

(21) Appl. No.: 18/707,978

(22) PCT Filed: Mar. 25, 2022
(86) PCT No.: PCT/EP2022/058019

§ 371 Date: May 7, 2024

(30) Foreign Application Priority Data
Nov. 8, 2021 (EP) 21207018.9

(51) Int. Cl. G03F 7/00; G03F 1/66; H10P 72/10

(52) U.S. Cl. CPC G03F 7/70741; G03F 1/66; H10P 72/1906; H10P 72/1926

(57) ABSTRACT

Stocker system for storage of a plurality of reticles, especially EUV reticles, including a plurality of storage pods each adapted to hold one of the reticles in their interior, and to be stacked vertically one above the other to provide a stack, each of the storage pods including a passageway with an inlet, an outlet and a first opening, wherein inlets and outlets of adjacent passageways are arranged such that a duct extending through the stack is provided, through which a purge gas can be blown, and the purge gas blown through the duct can enter the interior of each storage pod through its respective first opening.

### CROSS-REFERENCE TO RELATED APPLICATIONS

This application is a National Stage of International Application No. PCT/EP2022/058019 having an International Filing Date of 25 Mar. 2022, which designated the United States of America, and which International Application was published under PCT Article 21(2) as WO Publication No. WO2023/078589 A1, which claims priority from and the benefit of European Patent Application No. 21207018.9, filed on 8 Nov. 2021, the disclosures of which are incorporated herein by reference in their entireties.

### BACKGROUND

### Field

The present disclosure relates to a stocker system for storage of reticles, especially EUV reticles, a corresponding storage stocker and a device for retrieving reticles. The disclosure further relates to methods for handling reticles.

### Brief Description of Related Developments

Photolithography processes are widely used as one of the key steps in the manufacture of integrated circuits (ICs) and other semiconductor-related devices and/or structures. However, as the dimensions of features produced by such processes decrease, the importance of photolithography for the production of miniature ICs or other devices and/or structures rises.

In photolithography, a geometric pattern is transferred from a photomask (typically referred to as reticle) onto a substrate, for example a semiconductor wafer, by the use of light, a photosensitive layer and a subsequent etching step. Depending on the desired feature size on the substrate, the feature size of the reticle needs to be adapted as well as the wavelength of the light used for pattern transfer, with consideration of the Rayleigh criterion.

In order to reduce the smallest achievable feature size, it has been proposed to use extreme ultraviolet (EUV) radiation. EUV radiation is electromagnetic radiation having a wavelength within the range of 5-20 nm, for example within the range of 5-10 nm.

Any contamination of the reticle may reduce the imaging performance of the photolithographic process and may in more serious cases require the reticle to be replaced. The reticle is typically expensive and therefore any reduction in the frequency with which it must be replaced is advantageous. Furthermore, replacement of the reticle is a time consuming process, during which the photolithographic process may have to be suspended, thereby reducing its efficiency, which is undesirable.

For EUV applications, particle contamination with particle sizes of less than 10 nm as well as chemical contamination, for example by adsorption of volatile organic compounds, can be relevant.

The reticles used for such EUV applications are therefore typically stored in a storage stocker, referred to in the following simply as a stocker, or more generally, as place of storage, and retrieved when needed in connection with the lithography exposure equipment. When they are to be used, reticles are transported, usually within a semiconductor fabrication plant, commonly referred to as a fab, from such a stocker to process tools. Usually, the reticles are stored in a double shell container (double pod) comprising a so-called EUV outer pod (EOP) and an EUV inner pod (EIP) during transportation as well as for storage within the stocker.

Such a double pod is described in further detail in US 2019/0214287 A1, for example.

Since the acceptable level of particle contamination is extremely low, friction (which leads to abrasion and thus particle generation) of the reticle against the container as well as friction of container components relative to one another needs to be avoided. Therefore, typical EIPs are designed so as to accommodate one reticle in such a way that it has only very limited possibilities to move therein. They are also equipped with an additional reticle retainer configured and adapted to immobilize the reticle inside the EIP. In order to prevent contamination, the EIP is designed to enable a protective gas or vacuum to be applied to the reticle. To that end, typically orifices equipped with filter material are provided for the protective gas to enter from the EOP into the surroundings of the reticle contained in the respective EIP.

The EOP is equipped with an actuator adapted to bias the reticle immobilization means of the EIP into a retaining position, thereby immobilizing the reticle inside the EIP when the EOP is attached to the EIP. The EOP also functions to immobilize the typically two components of the EIP, usually referred to as base plate and cover, against one another to prevent friction induced abrasion.

It is to be understood that the EIP components are moveable against one another as long as they are not immobilized from outside. In order to avoid friction induced abrasion caused by such movement, the EOP conventionally provides such immobilization functionality for the EIP while also providing protection against the surrounding atmosphere, which is necessary e.g. during transport between a storing position and process tools requiring reticles for operation.

EOPs are rather bulky, leading to high space requirements or “footprint” for stockers storing EUV reticles. Furthermore, they are made of polymeric material, which is also prone to abrasion and outgassing of volatile organic compounds.

### SUMMARY

The present disclosure addresses these problems by providing a stocker system, a storage stocker, a method of handling a reticle, a device and a method for retrieving a reticle pod from a stack of reticle pods and a storage pod according to the respective independent claims.

Advantageous embodiments and additional features are provided in the dependent claims and further discussed in the following description.

The disclosure provides a stocker system for storage of a plurality or reticles, especially EUV reticles, comprising a plurality of storage pods each adapted to hold one of said reticles in their interior, and to be stacked vertically one above the other to provide a stack, each of the storage pods comprising a passageway with an inlet, an outlet and a first opening, wherein inlets and outlets of adjacent passageways, or, in other words, the passageways of adjacent storage pods, are arranged such that a duct extending through the stack is provided, through which a purge gas can be transported, and the purge gas transported through the duct can enter the interior of each storage pod through its respective first opening.

The disclosure provides a highly compact and reliable storage system, as a plurality of storage pods can be stacked directly one above the other, without any storage structures therebetween. At the same time, by means of this direct stacking, a duct extending through all stacked storage pods for individually providing each storage pod with a purge gas can be formed. As an effective purge of the interiors of the storage pods can be provided according to the disclosure, the storage pods can be made of suitable plastics materials, as outgassing effects can effectively be counteracted by the purge gas flowing in the storage pods. The storage pods can also be made of metal materials.

Advantageously, the first opening of each passageway is provided with a particle filter, such that only the purge gas can enter the interior of each storage pod through the first opening. Hereby, individual environments can be provided for each storage pod, such that cross contamination between different storage pods within a stack can be effectively avoided.

Preferably, each storage pod is provided with a second opening, through which purge gas can exit the interior of the storage pod, wherein the second opening is also preferably provided with a particle filter. Providing these second openings with particle filters further minimises the risk of cross contamination.

Advantageously, each storage pod is provided with at least one handling member, such as a handling flange or a handle. Preferably, handling members can be provided on all four sides of a storage pod, such that a handling robot can grip the storage pod at the handling member without the necessity of a rotation of the storage pod. This significantly reduces handling times. Such a handling robot is preferably provided with at least one handling element, also known as an end effector, for handling, i.e. transporting, storage pods.

According to a preferred embodiment, each storage pod comprises a base plate and a cover, wherein alignment features configured and adapted to mechanically align adjacent storage pods in a stacked configuration are provided, wherein especially the base plate is provided with grooves or pins, and the cover is provided with pins or grooves, wherein grooves and pins are provided for interacting with corresponding pins or groves provided on adjacent storage pods. Such mating grooves and pins ensure a precise and exact alignment and positioning of storage pods in the stack. For example, adjacent storage pods stacked one above the other can respectively be provided with interacting pins, preferably dome shaped pins, often referred to as kinematic pins in the technical field, and correspondingly shaped recesses. Hereby, alignment and positioning of storage pods can be and at the same time a safeguard against horizontal movement of adjacent storage pods can be achieved. This is advantageous to ensure effective handling through handling robots.

Advantageously, each storage pod is provided with a latch mechanism for securing base plate and cover to one another. Such a latch mechanism can comprise a number of latches, and ensure a gas tight connection between base plate and cover, these components usually being made of a metal material. Especially, such a latch mechanism is adapted to prevent relative movement of base plate and cover relative to one another in a locked state, thereby preventing abrasion. Also, the latch mechanism can be adapted to immobilise a reticle within a storage pod relative to the storage pod, which also minimises abrasion and contamination effects.

The present disclosure also provides a storage stocker comprising such a stocker system and a storage entity adapted to store the stocker system. Such a storage stocker typically also includes an Equipment Front End Module (EFEM) including at least one loadport, and a storage area, in which the stocker system is located. The storage stocker is part of a semiconductor fab.

Advantageously, the storage stocker is provided with a securing mechanism, for example a clamping mechanism or a spring mechanism, to physically secure the individual storage pods to one another and/or to the storage entity in which the stack is stored. Hereby, an efficient safety measure against damage to individual storage pods or reticles housed therein due to earthquakes is provided. For example, a spring mechanism comprising at least one spring can be provided to continuously provide a downward force acting on the top of the stack. For example, the spring can be adapted to push down on a plate positioned above the uppermost storage pod. This plate can, for example, be provided with handles, for example shaped in a similar manner to handling members that can be provided on the storage pods, so that the handles and thus the plate can be lifted to access the top storage pod. The plate could be provided with alignment features (e.g., pins and/or holes) located on its lower side facing the storage pods, in order to engage corresponding alignment features such as holes and/or pins of the uppermost storage pod. A permanently empty storage pod in the top position could also be used instead of such a plate. The robot would work against the spring mechanism when it lifts the stack. A spring mechanism comprising at least one spring could also be provided underneath the stack, for example acting against a bottom plate under the stack of storage pods. Instead of or in addition to such a spring mechanism, a cam or other type of clamp mechanism could exert a force against a top plate, an uppermost storage pod, a bottom plate or a lowermost storage pod. Such a cam or clamp would then be actively released when access is desired.

Such a securing mechanism can be utilised in addition to gravity effects, which also assist in securing stacked storage pods stacked to one another.

The present disclosure also provides a method of handling a reticle, especially an EUV reticle, comprising the following steps: transportation of the reticle between a place of use, typically a semiconductor process tool, and a place of storage or storage area comprising a reticle stocker system as described in the present disclosure, or vice versa, in a transportation pod, transferring the reticle from the transportation pod to a storage pod, and storage of the reticle at the place of storage in the storage pod. By using different pods for transportation and storage, contamination effects for the reticle can be minimised, which is especially important in connection with EUV reticles.

Preferably, the transportation pod comprises at least an inner pod EIP, and the storage pod is adapted to hold one reticle in its interior, and to be stacked vertically one above the other with other storage pods to provide a stack, and wherein each storage pod comprises a passageway through which a purge gas can be transported, with an inlet, an outlet and a first opening, and the purge gas transported through the passageway can enter the interior of the storage pod through the first opening.

Advantageously, the transportation pod comprises an inner pod EIP and an outer pod EOP. EIPs and/or EOPs, from which a reticle has been removed and transferred to a storage pod, can themselves be stored in a transportation pod buffer, which can, for example, be provided above or in the vicinity of an EFEM handling robot.

The present disclosure enables reducing the required space for storing reticles while ensuring a lower level of contamination and improved damage protection over that as provided by conventional systems. This is due, in part, to the fact that storage pods as used in the present disclosure do not leave the stocker system, in contrast to EIPs, which were previously used for storage of reticles within stockers as well as transportation of reticles outside of stockers. Furthermore, chemical contamination during storage from outgassing EOPs is also prevented and mechanical damage protection improved over storing reticles in double pods. As mentioned, while prior art EIPs are typically made of metal materials to prevent outgassing, storage pods as used according to the present disclosure can be made of plastics materials, although it can also be advantageous to use metal materials.

The disclosure also provides a device for retrieving a first reticle pod (the term reticle pod as used herein is meant to comprise any pod configured and adapted to house a reticle, e.g., a transport pod such as an EIP or a storage pod) from a stack of reticle pods, comprising a first handling element for handling the first reticle pod, and a second handling element adapted to handle a second reticle pod, the second reticle pod being arranged adjacent and vertically above the first reticle pod within the stack of reticle pods, wherein the first handling element and the second element are adapted to be individually displaceable in a horizontal direction and jointly displaceable in a vertical direction such that the second reticle pod can be lifted off the first reticle pod and the first reticle pod can be lifted off a third reticle pod, the third reticle pod being arranged adjacent and vertically under the first reticle pod within the stack of reticle pods, the first reticle pod can be retrieved form the stack of reticle pods, and the second reticle pod can be placed on the third reticle pod.

Advantageously, the first handling element and the second handling element are adapted to have a vertical distance from one another that is greater than a vertical distance of respective handling members provided on the first and second reticle pods, with which the handling elements interact, in order to lift the second reticle pod off the first reticle pod and the first reticle pod off the third reticle pod.

Expediently, the vertical distance between the handling members is provided to be fixed. This simplifies the construction of the drive of the handling members in vertical direction, leading to enhanced reliability.

Expediently, the first and the second handling element are each provided to comprise two horizontally extending arms adapted to interact with handling members provided on opposite sides of the first and second reticle pod respectively.

Advantageously, the device comprises a drive adapted to individually displace the first handling mechanism and the second handling mechanism in a horizontal direction, and to jointly displace the first handling mechanism and the second handling mechanism in a vertical direction.

The disclosure also provides a method for retrieving a first reticle pod from a stack of reticle pods using a device as described.

Herein, the first handling element and the second handling element are advantageously jointly displaced in a horizontal direction in order to position the first handling element under a first handling member of the first reticle pod and the second handling element under a second handling member of the second reticle pod, the first handling element and the second handling element are jointly displaced in a vertical direction, i.e. upwardly, to lift the second reticle pod off the first reticle pod and the first reticle pod off off a third reticle pod, the third reticle pod being arranged adjacent and vertically under the first reticle pod within the stack of reticle pods, the first handling element is individually displaced in a horizontal direction to retrieve the first reticle pod from the stack of reticle pods, the first handling element and the second handling element are jointly displaced in a vertical direction, i.e. downwardly, to place the second reticle pod on the third reticle pod, and the second handling element is displaced in a horizontal direction to separate it from the second reticle pod. Hereby, an individual storage pod can be easily retrieved from a stack containing n storage pods with minimal displacement of handling elements, thus providing a storage pod that can be further handled individually and a stack comprising n-1 storage pods.

Aspects which need to be taken into account when developing such an improved storage concept include that it is highly undesirable to change the way the reticles are provided to the photolithographic process equipment, this typically being the most complicated and costly part of a semiconductor production facility.

Be it noted that all the method steps discussed herein can advantageously be carried out in an automated manner, for example by one or more robotic components.

The disclosure also provides a storage pod configured and adapted to store a reticle within a stocker, comprising a base plate and a cover, wherein a latch mechanism is provided for holding together base plate and cover in a releasable manner, the storage pod being provided with alignment features configured and adapted to enable mechanical alignment with an adjacent storage pad in case of a stacked configuration. Preferably, adjacent storage pods aligned in this way in a stacked configuration are provided to be essentially identical to one another.

Advantageously, the storage pod comprises a passageway with an inlet, an outlet and a first opening, wherein inlet and outlet are configured and adapted such that inlets and outlets of adjacent passageways of adjacent storage pods in the stacked configuration are arranged such that a duct extending through the stacked configuration is provided, through which a purge gas can be transported, and wherein the first opening is configured and adapted such that purge gas transported through the duct can enter an interior of the storage pod through its first opening.

The disclosure thus provides a two part storage pod having complementary alignment features (e.g., pins and holes) on its top and bottom surfaces such that pods can be stacked one on top of one another, thus facilitating automation of handling.

The advantageous provision of storage pods with alignment features can also be provided for storage pods without inlets, outlets and openings for transportation of purge gas as described above.

### BRIEF DESCRIPTION OF THE DRAWINGS

Advantages and further aspects of the disclosure will now be discussed further with reference to the appended drawings. Herein,

FIG. 1 shows a perspective view of a preferred embodiment of two identical storage pods for use in a stocker system according to a preferred embodiment of the disclosure,

FIG. 2 shows a perspective view of a base plate of one of the storage pods as shown in FIG. 1 together with a reticle,

FIG. 3 shows a schematical side view of a stocker system according to a preferred embodiment of the disclosure,

FIG. 4 shows a plan view of the base plate as shown in FIG. 2,

FIG. 5 a schematical side sectional view of a storage pod according to a preferred embodiment of the disclosure,

FIG. 6 shows a schematical plan view of a preferred embodiment of a storage stocker according to the disclosure, in connection with which a stocker system according to the present disclosure can be used, and

FIGS. 7a to 7d show schematical views of a preferred embodiment of a method for retrieving a storage pod from a stack of storage pods.

### DETAILED DESCRIPTION

Due to very strict cleanliness requirements, EUV reticles are typically transported between their place of use, such as a process tool, and a place of storage, usually referred to as a reticle stocker or storage stocker, in double shell containers (double pods) comprising a so-called EUV outer pod (EOP) and an EUV inner pod (EIP). These EOPs have dimensions, i.e. sizes and shapes compatible with SEMI 152 standards, to ensure safe and reliable handling with standard fab transportation systems, such as overhead hoist transport (OHT), overhead shuttle (OHS), automated guided vehicles (AGV), person guided vehicle (PGV) and rail guided vehicle (RGV).

Previously, reticles were also stored in these double pods within the storage stockers. Due to the large volume requirements of such a storage, recent suggestions have included storing the reticles within the stocker in EIPs only. This storage within EIPs requires additional measures to fixate the reticles within the EIPs, and also to fixate the EIP components relative to one another.

The present disclosure makes use of the idea of transferring the reticles for storage in a storage stocker from the EIPs of double pods used for transportation as described above into dedicated storage pods, which have similar overall dimensions as EIPs, but can be stacked directly one above the other within the stocker, thereby further reducing the total required storage volume within a stocker.

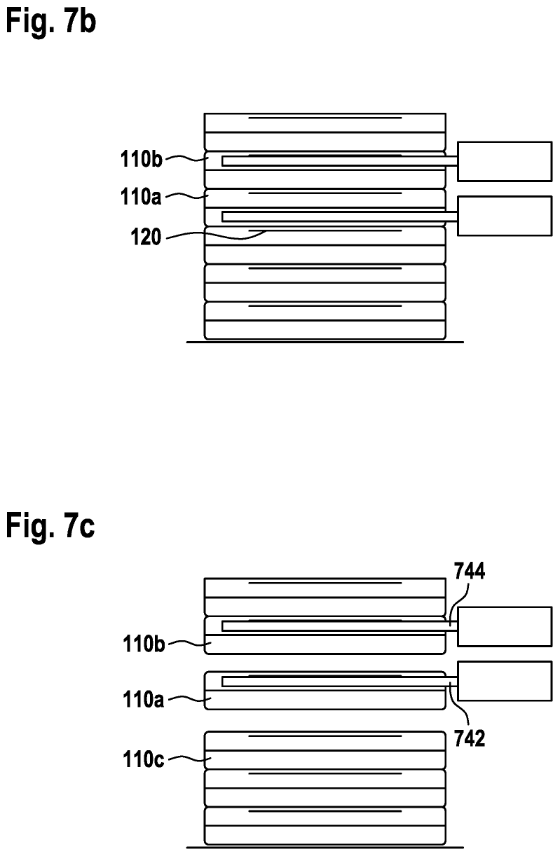

This general concept will now be further explained with reference to FIG. 6, which shows the main components of a storage stocker.

The storage stocker shown in FIG. 6 is generally designated 600. It comprises an Equipment Front End Module (EFEM) 620 comprising two loadports 610 (one of which is shown holding an EUV double pod 611, and the other of which is shown empty, for illustration purposes), an EFEM handling robot 622 and an EIP opener station 624. The storage stocker 600 further comprises a storage area 640, including a storage pod opener station 642, a storage robot 644, and storage shelves 660, which are adapted to hold stacks of storage pods containing reticles, especially stocker systems according to the disclosure. For illustration purposes, a storage pod 661 is shown in connection with storage shelves 660.

The EFEM handling robot 622 and the storage robot 644 are typically provided with two end effectors 622a,622b and one end effector 644a respectively. End effectors are provided as gripping or handling mechanisms. The first end effector 622a of the EFEM handling robot 622 is adapted to handle and move EIPs, and the second end effector 622b of the EFEM handling robot 622 is adapted to handle and move bare reticles: The storage robot 644 can also be provided with two end effectors adapted to handle and move the storage pod and the reticle respectively, but can also be provided with one end effector only, for example for handling only the storage pod, as shown in FIG. 6.

Typically, double pod (EUV pod) 611 comprising an outer pod EOP and an inner pod EIP, which contains a reticle to be stored in a storage stack within storage area 640 is delivered to one of the loadports 610 of EFEM 620. In loadport 610, the outer pod EOP is opened, so that the inner pod EIP, still containing the reticle to be stored can be removed from the outer pod EOP and transferred to the EIP opener station 624 by EFEM robot 622 using its first end effector. In an alternative embodiment, not further described here, it is also possible to open the inner pod within the loadport 610, and transfer the bare reticle directly to an opened storage pod provided in the storage pod opener station 642. In this alternative embodiment, it is not necessary to provide a designated EIP opener station, such as EIP opener station 624, in addition to the loadport 610.

In EIP opener station 624, the inner pod EIP is opened so that the bare reticle contained within the EIP becomes accessible. At the same time, storage robot 644 transfers a storage pod 661 from a storage stack on the storage shelves 660 to storage pod opener station 642, utilising its first end effector 644a. In storage pod opener station 642, the storage pod 661 is opened. EFEM robot 622 then transfers the bare reticle from the EIP opened in EIP opener station 624 to the opened storage pod in the storage pod opener station 642 utilising its second end effector 622b.

Then, the storage pod 661 in the storage pod opener station 642 is closed, and the storage pod 661 with the reticle therein is transferred back to the storage stack on the storage shelves 660 by the storage robot 644.

In order to transfer a reticle stored within a storage pod 661 in a storage stack on storage shelves 660 to the loadport 610, the above steps can be performed in reverse order.

Be it noted that the storage pod opener station 642 is advantageously provided as a lock between the storage area 640 and the EFEM. Hereby, distinct cleanliness level differences can be maintained in or between different sections of the storage stocker. Advantageously, the storage pod opener station 642 is provided with two doors (not shown in FIG. 6), a first one of which is openable towards the EFEM 620, and a second one of which is openable to the storage area 640. After a reticle is transferred into a storage pod in the storage pod opener section 642 through the first door, while the second door is closed, the first door is then also closed. In this state, the storage pod opener station 642 can be purged by a (not explicitly shown) purge gas system, to achieve a higher cleanliness level than, for example, that of the environment in the EFEM 620. This purge can be performed before and/or after the storage pod, with the reticle inside it, is closed.

When this has been achieved, the second door to the storage is opened, and the storage pod is transferred to the storage stack on the storage shelves 660.

A storage pod as used in the present disclosure remains inside the stocker during normal usage, i.e. for storing reticles, as it is not used for transportation of reticles within the semiconductor fab. It is, however, possible to remove the empty storage pod from the stocker for specific purposes, such as cleaning procedures. This removal of an empty storage pod from the stocker can advantageously be effected via the same path that the reticles take, i.e. via the EFEM handling robot. Thus, contamination of the storage pod, especially from the fab environment, can be minimised as compared to previous solutions.

The EFEM handling robot 622 can also be adapted to transfer an empty storage pod to one of the external load ports 610 where it can then be placed in a dedicated outer pod, in which it is transferred to a cleaning device. Advantageously, the EFEM handling robot 622 utilises its first end effector 622a herefor.

The EFEM advantageously comprises an AMC filtered FFU for class 1 mini environment Advantageously, a separation is provided between the EFEM, and the fab environment, as well as between the EFEM and storage area 640 for storage pods.

An EFEM is usually with multiple load ports, such as load ports 610 as mentioned above, for standard EUV pods according to the standard SEMI E152 used for transportation within a fab between the different items of equipment. These load ports are adapted to open EUV pods, especially EOPs, as also described above. The load ports may also be adapted to open EIPs, in order to gain access to the bare reticle inside, although this variant is not explicitly shown in the figures.

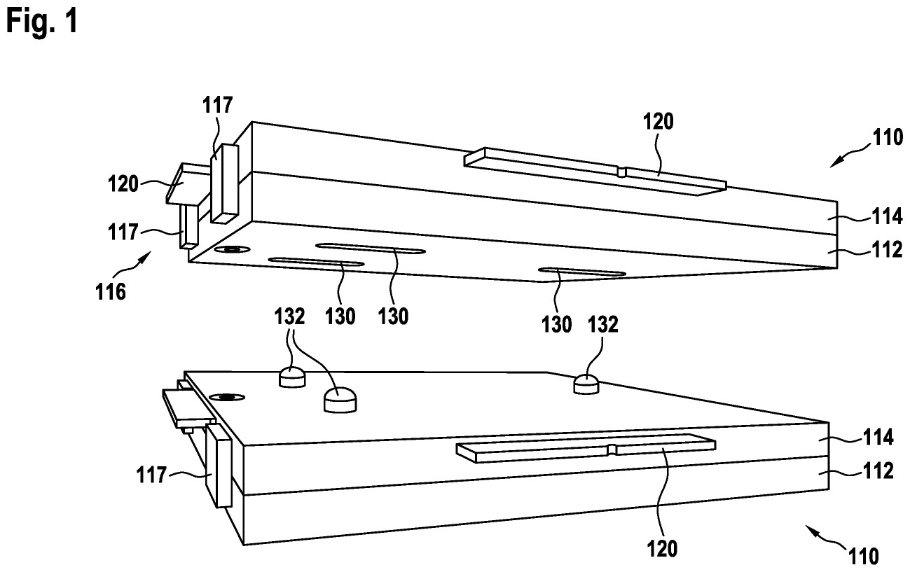

In FIG. 1, two storage pods each adapted for storing a reticle within a reticle stocker are designated 110. Each storage pod 110 comprises a base plate 112 and a cover 114. FIG. 1 shows the storage pods 110 in their closed state, in which they usually house a reticle.

Base plate 112 and cover 114 are held together by a latch mechanism 116, of which two latches 117 provided on the front side of the storage pod 110 are visible in FIG. 1. Two further latches, which are not visible in FIG. 1, are provided on the rear side of the storage pod 110. Typically, the latch mechanism can be provided to define three states, a locked state, in which base plate 112 and cover 114 are tightly closed, providing a protected interior therebetween, an unlocked state, in which base plate 112 and cover 114 can be separated from one another, for example in order to load or unload reticles, and an idle state, in which the latches 117 are disabled for usage in or with other tools, for example for cleaning. Typically, the latches 117 remain in the idle position, until they are actively returned to the locked or unlocked states.

The latch mechanism 116 serves to hold baseplate 112 and cover 114 together during storage in the reticle stocker and transportation to and from a transfer station (e.g., a storage pod opener station, 624), in which the reticle is transferred from an EIP of a double pod to a storage pod 110 or vice versa. Be it noted that the latch mechanism may hold baseplate and cover together in an airtight manner to provide a separate atmosphere in the inside of a storage pod, thus minimising contamination from the outside. Also, in case of for example a positive gas pressure in the inside of the reticle pod, it is not necessary for the clamp mechanism to hold baseplate and cover together in an airtight manner in order to minimise contamination inside the storage pod. A transfer station of this kind is typically integrated in a reticle stocker. Advantageously, in the locked position, the latch mechanism serves to prevent any movement of the base plate 112 and the cover 114 relative to one another, thereby minimising or avoiding any abrasion effects during storage of reticles, which can lead to unacceptable contamination.

The EFEM mentioned above is provided to comprise a storage pod opening mechanism, which can activate and deactivate the latch mechanism 116.

The storage pods 110 are provided with a mechanism for fixing a reticle inside the storage pod, when the storage pod is in its closed position, which further minimises potential contamination due to abrasion effects caused by movement of the reticle in the storage pod. Advantageously, the latch mechanism 116 is adapted to fix the base plate and the cover relative to one another, as mentioned above, and the reticle relative to the storage pod.

On each side of the storage pods 110, there is provided a handling member 120, such as a handling flange or a handle. Providing handling members on each side enables a handling robot to grip the storage pod 110 from any side, without the necessity of rotating the storage pod. In the embodiment shown, the side handling members are provided on the cover 114. It is also conceivable to provide them on the base plate 112, or for example two on opposite sides of the base plate, and two on different opposite sides of the cover, whereby individual handling of the base plate or the cover by the handling robot is rendered possible or at least simplified.

Base plates and covers are advantageously provided with complementary alignment features to enable or facilitate physical or mechanical alignment of storage pods in a stacked configuration. In the embodiment shown in FIG. 1, for example, each base plate 112 is provided with a plurality of grooves 130 formed in its lower side. Each cover is provided with a corresponding plurality of pins (“kinematic pins”) 132 on its upper side.

Alternatively, each base plate could be provided with a plurality of pins, and each cover with a plurality of corresponding grooves. Grooves 130 and pins 132 are formed and positioned to mate with one another such that an exact alignment of the storage pods is provided when they are stacked one above the other. Such an exact alignment is a precondition for effective robot handling by a handling robot. Advantageously, the grooves 13 are provided as elongated holes or slots. As can be seen in FIG. 1, the two pins 132 on the left side of the cover 114 interact with the left ends of associated grooves 130, whereas the pin 130 on the right side of the cover interacts with the right end of associated groove 130. Hereby, a relative movement of base plate and cover is effectively avoided, while the remaining sections of groves 130, i.e. the sections not interacting with the respective pins, can be utilised for other purposes, such as handling purposes.

In order to remove a targeted storage pod from a stack of storage pods, the handling robot lifts a partial stack comprising all storage pods arranged above the targeted storage pod by gripping a flange 150 of the lowermost storage pod in this partial stack, so that it can then easily access the targeted storage pod 110. The individual storage pods can have a fixed or dedicated position within a stack, or can be randomly positioned. Advantageously, every storage pod is provided with an identification code, for example in form of an RFID.

The dimensions of the storage pods 110, i.e. their size and shape, are preferably fully compatible with existing fully automated EUV pod cleaning equipment.

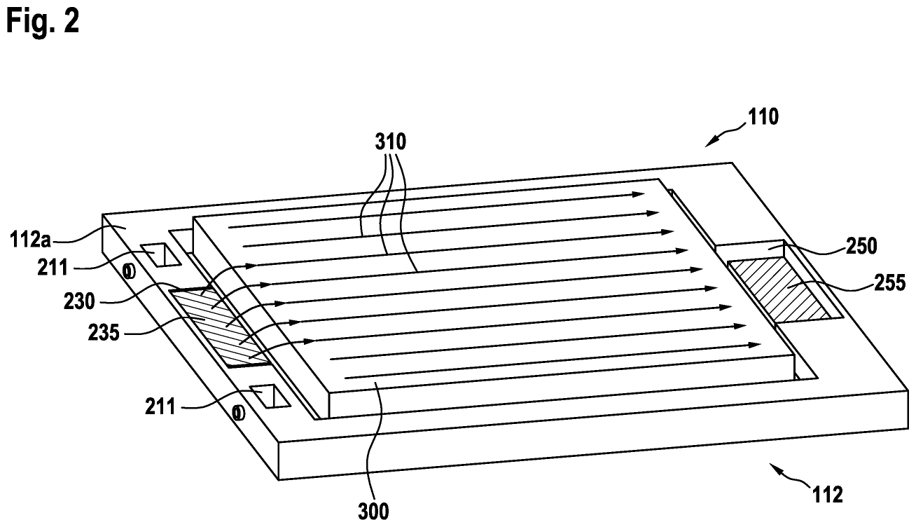

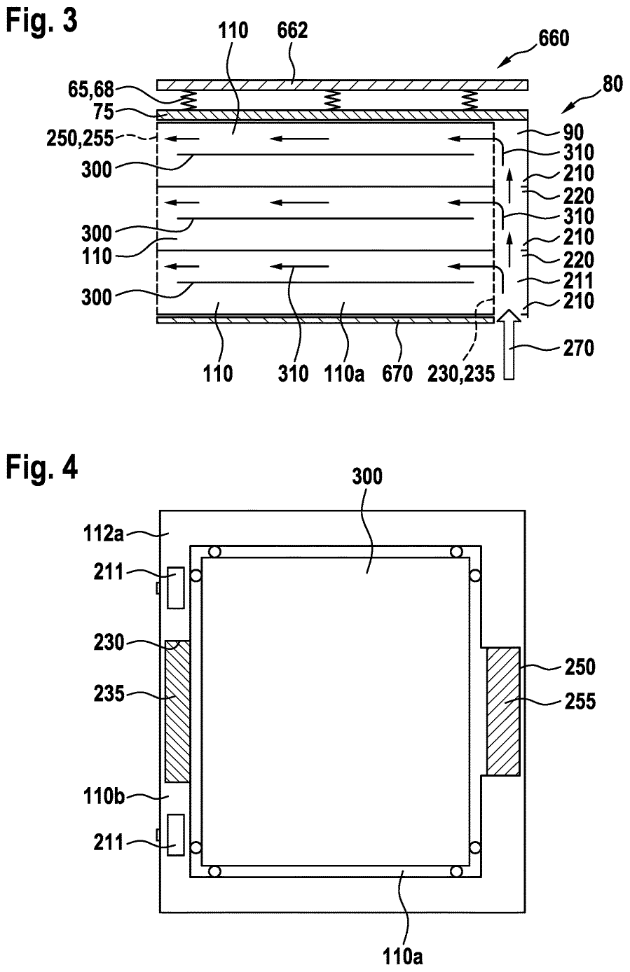

In FIG. 2, a base plate 112 of a storage pod 110 is shown without a cover. On the base plate, there is positioned a reticle 300. During normal use of the storage pod 110, i.e. to store a reticle within a stocker, the cover (not shown in FIG. 2) together with the base plate 112 as shown provides a protected interior for reticle 300. The reticle 300 is thus housed within an interior of the storage pod 110. This interior is designated 110a in FIGS. 3, 4 and 5, and will be further discussed below.

The stocker system also provided a purge gas flow for the respective storage pods, which will be further described in the following, especially referring to FIGS. 2 to 5.

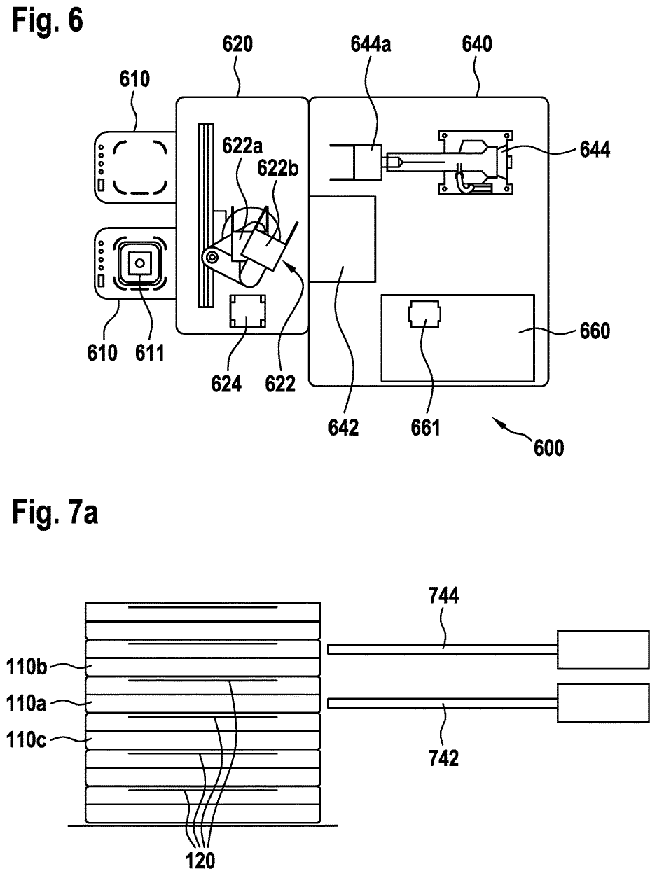

Referring especially to FIGS. 3 and 5, the base plate 112 of each storage pod is provided with an inlet 210, through which a purge gas can, on the one hand, flow though a passageway 211 (provided in the base plate and in the corresponding cover) to an outlet 220 provided in the corresponding cover (symbolised by arrows 211 a in FIG. 5), and on the other hand into the interior of a storage pod via an opening 230 provided with a filter 235, preferably a PTFE filter, thus providing a purge flow for a reticle 300, as indicated by arrows 310 in FIGS. 2, 3 and 5. The purge gas can exit the interior 111a of the storage pod 110 at the opposite side of the base plate through a purge gas outlet 250, which is also provided with a filter 255, preferably a PTFE filter.

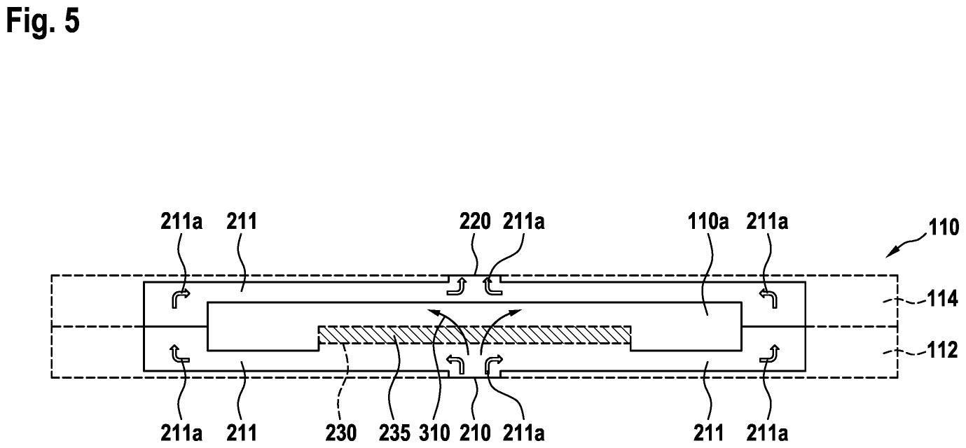

The general principle of this purge gas flow through the stocker system is illustrated in FIG. 3, while a preferred embodiment is shown in FIGS. 4 and 5, and also in FIG. 2.

As to FIG. 3, this schematically shows three storage pods 110 stacked one above the other to provide a stack 80. Base plates and covers of the storage pods 110 are not explicitly referenced in FIG. 3. Each storage pod 110 houses a reticle 300.

The stack 80 is arranged on a shelf plate 670, which is a part of a storage shelf 660 of a storage entity, as mentioned above in connection with FIG. 6. On top of the stack 80, a cover plate 75 is provided. Advantageously, in order to stabilize the stack 80, especially to prevent damage caused by inadvertent agitation caused for example by an earthquake, there can be provided a securing mechanism, such as a spring mechanism or a clamp mechanism, for securing the storage pods 110 of the stack 80 to one another, and also for securing the stack 80 as a whole to the storage entity, for example the storage shelf 660 as mentioned above, in which it is positioned. In some embodiments, storage shelf 660 and/or cover plate 75 include alignment features (e.g., pins and/or grooves) complementary to alignment features of storage pods located in the bottom and/or top storage pod positions of stack 80.

In the embodiment as shown in FIG. 3, a schematically shown spring mechanism 65 comprising a number of spring elements 68 arranged between cover plate 75 and an underside of a storage shelf 662, such that a continuous downward force acts against cover plate 75 and thus on the stack 80. As will be readily appreciated, such a spring mechanism could also be provided under the lowermost storage pod to provide an upwardly directed force acting the stack 80 from below.

As mentioned above, each storage pod 110 is formed with an inlet 210 (provided in the base plate not explicitly designated in FIG. 3) and an outlet 220 (provided in the cover, also not explicitly designated in FIG. 3). The inlet and the outlet of a storage pod are in communication with one another via a passageway 211 extending through each storage pod 110. Each outlet 220 is immediately adjacent to an inlet 210 of an adjacent storage pod 110. Thus, a duct 90 is formed, which extends through the whole stack 80 in a generally vertical direction.

Each passageway 211 is also provided with a first opening 230 into the interior 110a of the respective storage pod 110. Each first opening is advantageously provided with a filter 235, which allows a purge gas transported or blown through duct 90 to enter the interior 110a of each storage pod, but prevents contamination by particles present in the purge gas within duct 90, as will be further explained in the following. Again, this purge gas flow into and through the respective storage pods 110 is symbolised by arrows 310.

All in all, a purge gas from a purge gas supply (not shown) is vertically transported through an opening in the shelf plate 70 into the duct 90 formed by the passageways 211 of the stacked storage pods 110 (indicated by arrow 270 in FIG. 3). The upper end of the duct 90 is defined by cover plate 75, which blocks the flow of purge gas. This flow of purge gas through duct 90 and the respective storage pods 110 is effected by providing corresponding pressure differences, for example by using pressurised purge gas and/or a ventilator system (both not shown).

As mentioned, a part of this purge gas enters the respective interiors 110a of the storage pods 110 through first openings 230, thus providing an essentially horizontal purge gas flow around a reticle 300 in each storage pod 110. At the side of the storage pods opposite the passageways 211, the purge gas exits the storage pods 110 through respective second openings 250, which are also provided with particle filters 255.

By providing a common purge gas supply (pressure plenum) via duct 90, and at the same time providing filters in the first openings 230 and the second openings 250, a highly effective purge gas flow can be individually provided through each storage pod 110 in stack 80. The storage pods 110 thus act as individual storage environments for respective reticles, wherein cross contamination between different storage pods 110 can be effectively avoided. Each storage pod 110 is provided with fresh, uncontaminated purge gas at any time.

Referring now to FIGS. 4 and 5, and also to FIG. 2, a preferred embodiment of the openings and passageways adapted to provide the purge gas flow through the individual storage pods 110 and the stack 80 will be described. Be it noted that the contours of base plate 112 and cover 114 are depicted in dashed lines in FIG. 5.

In the lower side of first side wall of base plate 112, designated 112a in FIGS. 2 and 4, opening 210 is formed, through which purge gas enters passageway 211. Covers 114 are provided with corresponding passageways 211, as visible in FIG. 5.

Through passageways 211 formed in the base plates 112 and the covers, purge gas can be transported through individual storage pods 110. In case a plurality of storage pods 110 are stacked upon one another, this purge gas flow can be provided through all said storage pods 114, from the lowermost one to the uppermost one within the stack. Part of the purge gas flowing through passage ways 211, and thus through duct 80 as discussed above with reference to FIG. 3 does not enter the interiors of the respective storage pods.

At the same time, in each storage pod 110, another part of the purge gas flow enters the interiors 110a through the openings 230, provided with a filter 235. This part of the purge gas provides an effective purge for a reticle stored in the storage pod and exits the storage pod via opening 250m which is also provided with a filter 255, as also discussed above with reference to FIG. 3.

Be it noted that while, according to the embodiment as shown in FIG. 3 the purge gas enters the interior 110a of the storage pods through a vertically extending filter 235, i.e. the initial purge gas flow within the interior is essentially horizontal, according to the embodiment of FIGS. 2, 4 and 5, the filter 235 is arranged to extend essentially horizontally, such that the initial flow into the interior 110a of the storage pod is vertical, or at least has a vertical component, as indicated by the left sides of arrows 310 in FIG. 2 or the arrows 310 in FIG. 5.

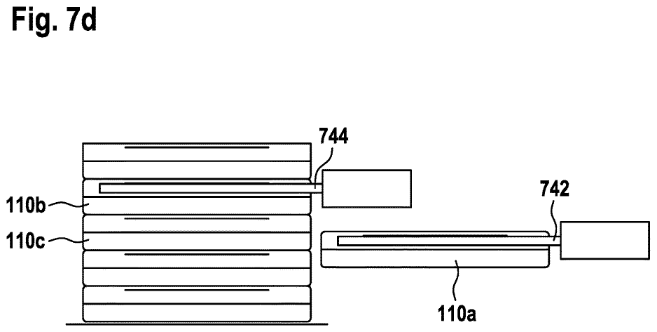

FIGS. 7a to 7d show a preferred embodiment of a method of retrieving a storage pod from a stack of storage pods. In the example shown, the stack comprises 6 storage pods 110. For ease of reference, a first storage pod is designated 110a, a second storage pod vertically adjacent and above the first storage pod is designated 110b, and a third storage pod vertically adjacent and below the first storage pod is designated 110c. Just for clarification purposes, the terms vertical, above and below/under as used in this specification refer to the direction of gravity, above meaning further away, and below or under closer to the centre of the earth, and the term horizontal refers to a direction extending at a right angle to the direction of gravity.

Each storage pod 110 is provided with two horizontally extending handling members 120, for example handling flanges or handles, on opposite sides, only one of which is visible for each storage pod in FIGS. 7a to 7c.

A device for retrieving an individual storage pod from the stack of storage pods is designated 740. Expediently, device 740 is part of a storage robot 640, as shown in FIG. 6.

Device 740 is provided with two handling elements 742 and 744, each comprising two horizontally extending arms or grippers for engaging with respective handling members 120 on opposite sides of the storage pods 110. Only one arm per handling element is visible in FIGS. 7a to 7d.

The handling elements are displaceable by a drive mechanism not shown in FIGS. 7a to 7d. The drive mechanism is also expediently part of storage robot 640, as shown in FIG. 6. The drive mechanism is adapted to displace handling elements 742 and 744 in a vertical as well as a horizontal direction. As will be shown in the following, the drive mechanism is designed to move handling elements jointly or individually in a horizontal direction, and jointly in a vertical direction. This means, that for separate horizontal movement of handling elements 742 and 744, two separate drives are provided, while for vertical movement of handling elements 742 and 744 only one drive is necessary.

In a first step, the handling elements 742 and 744 (in the perspective of FIGS. 7a to 7d) positioned to the right of the stock of storage pods 110 in FIG. 7a are displaced to the left, so that handling element 742 is positioned under the handling members 120 of first storage pod 110a, and handling element 744 under the handling members of second storage pod 110b. As can be seen in FIGS. 7a to 7d, the vertical distance between handling elements 742 and 744 is slightly larger than that of the handling members of first and second storage pods 110a and 110b, such that in the position shown in FIG. 7b, the vertical distance between handing element 742 and the handling members of first storage pod 110a is slightly larger than that between handling element 744 and the handling members of second storage pod 110b.

This means that if handling elements 742 and 744 are jointly moved vertically upwards, initially second storage pod 110b is lifted off first storage pod 110a, and subsequently first storage pod 110a is lifted off third storage pod 110c. As a consequence, first storage pod 110a, which is no longer in contact with adjacent storage pods 110b, 110c can easily be retrieved from the stack by a horizontal movement of handling element 742 (to the right in the perspective of FIG. 7c). By means of a subsequent joint vertical downward movement of handling elements 742 and 744, the second storage pod 110 can then be placed on third storage pod 110c This resulting situation is shown in FIG. 7d. Handling element 744 can then also be moved to the right, for example to return to the position shown in FIG. 7a.

While, as mentioned above, the vertical displacement of the handling elements 742,744 can advantageously by provided by a single drive, it would also be possible to provide this vertical displacement using one drive and a transmission mechanism connecting the two handling elements such that they can move apart from one another in the vertical direction, or by providing each one of the two handling elements with an individually controllable vertical drive.

What is claimed is:

1. A stocker system for storage of a plurality of reticles, especially EUV reticles, comprising a plurality of storage pods each adapted to hold one of said reticles in their interior, and to be stacked vertically one above the other to provide a stack, each of the storage pods comprising a passageway with an inlet, an outlet and a first opening, wherein inlets and outlets of adjacent passageways are arranged such that a duct extending through the stack is provided, through which a purge gas can be transported, and the purge gas transported through the duct can enter the interior of each storage pod through its respective first opening, wherein the first opening of the passageway is provided with a particle filter.

2. The stocker system according to claim 1, wherein each storage pod comprises a base plate and a cover, the inlet being provided in the base plate and the outlet being provided in the cover.

3. The stocker system according to claim 1, wherein each storage pod is provided with a second opening, through which purge gas can exit the interior of the storage pod, wherein the second opening is preferably provided with a particle filter.

4. The stocker system according to claim 1, wherein each storage pod is provided with at least one handling member.

5. The stocker system according to claim 1, wherein alignment features configured and adapted to mechanically align adjacent storage pods in the stack are provided, wherein especially the base plate is provided with grooves or pins, and the cover is provided with pins or grooves, wherein grooves and pins are provided for interacting with corresponding pins or groves provided on adjacent storage pods.

6. The stocker system according to claim 5, wherein each storage pod is provided with a latch mechanism for securing base plate and cover to one another.

7. A storage stocker comprising a stocker system according to claim 1 and a storage entity adapted to store the stocker system.

8. The storage stocker according to claim 7, comprising a securing mechanism adapted to physically secure individual storage pods to one another and/or to the storage entity.

9. A method of handling a reticle, especially an EUV reticle, comprising the following steps: transporting the reticle between a place of use and a place of storage, or vice versa, in a transportation pod, transferring the reticle from the transportation pod to a storage pod, or vice versa, and storing the reticle at the place of storage in the storage pod.

10. The method according to claim 9 wherein the transportation pod comprises at least an inner pod EIP, and the storage pod is adapted to hold/house one reticle in its interior, and to be stacked vertically one above the other with other storage pods to provide a stack, and each storage pod comprises a passageway through which a purge gas can be blown with an inlet, an outlet and a first opening, and the purge gas blown through the passageway can enter the interior of the storage pod through the first opening.

11. A device for retrieving a first reticle pod from a stack of reticle pods 100, comprising a first handling element for handling the first reticle pod, and a second handling element adapted to handle a second reticle pod, the second reticle pod being arranged adjacent and vertically above the first reticle pod within the stack of reticle pods 100, wherein the first handling element and the second element are adapted to be individually displaceable in a horizontal direction and displaceable in a vertical direction such that the second reticle pod can be lifted off the first reticle pod and the first reticle pod can be lifted off a third reticle pod the third reticle pod being arranged adjacent and vertically under the first reticle pod within the stack of reticle pods100, the first reticle pod can be retrieved form the stack of reticle pods and the second reticle pod can be placed on the third reticle pod.

12. The device according to claim 11, wherein the first handling element and the second handling element are adapted to have a first vertical distance from one another that is greater than a second vertical distance of respective handling members provided on the first and second reticle pods when the second reticle pod is stacked on the first reticle pod, with which the handling elements interact in order to lift the second reticle pod off the first reticle pod and the first reticle pod off the third reticle pod.

13. The device according to claim 12, wherein the first vertical distance is a fixed vertical distance.

14. The device according to claim 11, wherein the first and the second handling element are each provided to comprise two horizontally extending arms adapted to interact with handling members provided on opposite sides of the first and second reticle pod respectively.

15. The device according to claim 11, comprising a drive adapted to individually displace the first handling mechanism and the second handling mechanism in a horizontal direction, and to jointly displace the first handling mechanism and the second handling mechanism in a vertical direction

16. A method for retrieving a first reticle pod )from a stack of reticle pods using a device according to claim 11.

17. The method according to claim 16, wherein the first handling element and the second handling element are jointly displaced in a horizontal direction in order to position the first handling element under a handling member of the first reticle pod and to position the second handling element under a handling member of the second reticle pod, the first handling element and the second handling element are displaced in a vertical direction to lift the second reticle pod off of the first reticle pod and the first reticle pod off of a third reticle pod the third reticle pod being arranged adjacent and vertically under the first reticle pod within the stack of reticle pods, the first handling element is individually displaced in a horizontal direction to retrieve the first reticle pod from the stack of reticle pods, the second handling element is displaced in a vertical direction to place the second reticle pod on the third reticle pod, and the second handling element is displaced in a horizontal direction to separate it from the second reticle pod.

18. A storage pod configured and adapted to store a reticle within a stocker, comprising a base plate and a cover, wherein a latch mechanism is provided for holding together base plate and cover in a releasable manner, the storage pod being provided with alignment features configured and adapted to enable mechanical alignment with an adjacent storage pod in a stacked configuration of storage pods, further comprising a passageway with an inlet, an outlet and a first opening, wherein inlets and outlets are configured and adapted such that inlets and outlets of adjacent passageways of adjacent storage pods in a stacked configuration are arranged such that a duct extending through the stacked configuration is provided, through which a purge gas can be transported, and wherein the first opening is configured and adapted such that purge gas transported through the duct can enter an interior of the storage pod through its first opening, wherein the first opening of the passageway is provided with a particle filter, wherein the first opening of the passageway is provided with a particle filter.

19. (canceled)
